(19) United States
(12) Patent Application Publication
(10) Pub. No.: US 2025/0364364 A1
(43) Pub. Date: Nov. 27, 2025

(54) POWER MODULE

(71) Applicants: Hyundai Motor Company, Seoul (KR); Kia Corporation, Seoul (KR)

(72) Inventor: Tae Hwa Kim, Hwaseong-si (KR)

(73) Assignees: Hyundai Motor Company, Seoul (KR); Kia Corporation, Seoul (KR)

(21) Appl. No.: 18/948,036

(22) Filed: Nov. 14, 2024

(30) Foreign Application Priority Data
May 27, 2024 (KR) 10-2024-0068800

(51) Int. Cl. H01L 23/46; H01L 23/495

(52) U.S. Cl. CPC H01L 23/46; H01L 23/49568

(57) ABSTRACT

In the power module, a substrate and a cooling passage are directly coupled together, so cooling performance of the power module is improved. Furthermore, it is possible to improve cooling performance and secure watertightness of the cooling channel through a connection structure of a substrate, a cooling passage, and a cooling cover that form the cooling channel. Furthermore, it is easy to manufacture and manage the power module, and the operation performance and the operation reliability of the power module are improved because the cooling performance and watertightness of the power module are secured, so that the power density of an inverter applied to the power module may be increased.

### CROSS REFERENCE TO RELATED APPLICATION

The present application claims priority to Korean Patent Application No. 10-2024-0068800, filed May 27, 2024, the entire contents of which is incorporated herein for all purposes by this reference.

### BACKGROUND OF THE PRESENT DISCLOSURE

### Field of the Present Disclosure

The present disclosure relates to a power module that has a characteristic of heat dissipation, secures watertight performance in a direct cooling type, and is easy to manufacture and manage.

### Description of Related art

Recently, eco-friendly vehicles using an electric motor as a power source are increasing with the increase in interest in the environment. An eco-friendly vehicle is also called an electrified vehicle, and an Electric Vehicle (EV) and a Hybrid Electric Vehicle (HEV) are representative of eco-friendly vehicles.

Such electrified vehicles are provided with an inverter for converting DC power into AC power when a motor is driven and the inverter may be composed of one or a plurality of power modules having a semiconductor chip that performs a switching function.

Meanwhile, the operation process of a power module is accompanied with heat generation of a semiconductor chip due to a high-voltage high current. When the temperature of a power module increases due to heat generated by a semiconductor chip, as described above, the operation of the power module is influenced, so it is required to solve the problem of heat generation for stable operation of the power module.

Accordingly, various cooling types are applied to solve the problem of heat generation in a power module and cooling efficiency is improved through heat-exchange between a refrigerant and a substrate, for example, by connecting a cooling channel to the substrate and supplying the refrigerant into the cooling channel.

This cooling channel connection type may be classified into an indirect cooling type and a direct cooling type.

First, the indirect cooling type is a type that inserts a material such as a Thermal Interface Material (TIM) between a substrate and a cooling channel so that heat transfers to the cooling channel from the substrate.

The direct cooling type is a type in which heat transfers with a substrate and a cooling channel directly coupled to each other. However, since a cooling channel is directly coupled to a substrate in the direct cooling type, watertight performance should be secured, but when the structural design is complicated, it is difficult to secure watertight performance.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module which is easy to manufacture and manage, secures watertight performance, and improves power density of an inverter by improving cooling performance by changing a connection structure for a cooling channel.

To achieve the objectives, a power module according to an exemplary embodiment of the present disclosure includes: an insulating substrate including a first metal layer, an insulating layer, and a second metal layer in which a semiconductor chip is disposed on the first metal layer and a heat dissipation portion is formed on the second metal layer; a cooling passage forming a cooling channel; and a passage cover including an opening so that the insulating substrate is inserted therein, configured to hermetically seal the cooling channel by being coupled to the second metal layer and the cooling passage, and including the second metal layer coupled to the opening with the insulating layer inserted in the opening.

The passage cover and the second metal layer may be made of the same material.

When the insulating substrate is inserted in the opening of the passage cover, the second metal layer may be positioned to be matched to the passage cover in a direction perpendicular to an insertion direction of the insulating substrate.

An external edge portion of the second metal layer and an internal edge portion of the opening may be coupled by welding with the insulating substrate inserted in the opening of the passage cover.

Beads may be formed by welding at an interface between the second metal layer and the opening.

The beads may be formed on the second metal layer toward the cooling passage.

The cooling passage may form a sealed space therein by coupling the passage cover thereto and a sealer may be disposed at a joint between the cooling passage and the passage cover.

The heat dissipation portion may include at least one or more fins extending from the second metal layer toward the cooling passage.

The passage cover may be made of clad metal formed by stacking and coupling different materials.

The passage cover may be made of a first material and a second material, the first material may be the same as the material of the second metal layer, and the second material may be the same as the material of the cooling passage.

The first material of the passage cover may be coupled to the second metal layer and the cooling passage, and the second material of the passage cover may be positioned opposite to the cooling passage.

The first material of the passage cover may be coupled to the second metal layer and the second material of the passage cover may be disposed between the first material and the cooling passage and coupled to the cooling passage.

The second metal layer may be divided into a first layer and a second layer, the first layer may be bonded to the insulating layer, the heat dissipation portion may be formed on the second layer, and the first layer and the second layer may be bonded to each other through an adhesive.

When the insulating substrate is inserted in the opening of the passage cover, the second layer may be positioned in the opening of the passage cover and coupled to the passage cover.

The second metal layer of the insulating substrate and the passage cover may be coupled to each other through a connecting member.

The connecting member may be welded to the second metal layer on a first side and welded to the passage cover on a second side, and beads may be formed toward the cooling passage in welding.

The connecting member may be a portion of the second metal layer or the passage cover.

According to the power module including the structure described above, the substrate and the cooling passage are directly coupled together, so that the cooling performance of the power module is improved.

Furthermore, it is possible to improve cooling performance and secure watertightness of the cooling channel through a connection structure of a substrate, a cooling passage, and a cooling cover that form the cooling channel.

Furthermore, it is easy to manufacture and manage the power module, and the operation performance and the operation reliability of the power module are improved because the cooling performance and watertightness of the power module are secured, so that the power density of an inverter applied to the power module may be increased.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a view showing a power module according to an exemplary embodiment of the present disclosure;

FIG. 2 is a view showing a double-sided-cooling power module according to an exemplary embodiment of the present disclosure;

FIG. 3 is a view showing various exemplary embodiments of a power module according to an exemplary embodiment of the present disclosure;

FIG. 4 is a view showing various exemplary embodiments of a power module according to an exemplary embodiment of the present disclosure;

FIG. 5 is a view showing various exemplary embodiments of a power module according to an exemplary embodiment of the present disclosure; and

FIG. 6 is a view showing various exemplary embodiments of a power module according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereafter, various exemplary embodiments of the present disclosure will be described in detail with reference to the accompanying drawings and the same or similar components are provided the same reference numerals regardless of the numbers of figures and are not repeatedly described.

Terms “module” and “unit” that are used for components in the following description are used only for the convenience of description without including discriminate meanings or functions.

In the following description, if it is decided that the detailed description of known technologies related to the present disclosure makes the subject matter of the exemplary embodiments described herein unclear, the detailed description is omitted. Furthermore, the accompanying drawings are provided only for easy understanding of embodiments included in the specification, the technical spirit included in the specification is not limited by the accompanying drawings, and all changes, equivalents, and replacements should be understood as being included in the spirit and scope of the present disclosure.

Terms including ordinal numbers such as “first” and “second” may be used to describe various components, but the components are not to be construed as being limited to the terms. The terms are used only to distinguish one component from another component.

It is to be understood that when one element is referred to as being “connected to” or “coupled to” another element, it may be directly connected to or directly coupled to another element or be connected to or coupled to another element with the other element therebetween. On the other hand, it should be understood that when one element is referred to as being “directly connected to” or “directly coupled to” another element, it may be connected to or coupled to another element without the other element therebetween.

Singular forms are intended to include plural forms unless the context clearly indicates otherwise.

It will be further understood that the terms “comprise” or “have” used in the present specification specify the presence of stated features, steps, operations, components, parts, or a combination thereof, but do not preclude the presence or addition of one or more other features, numerals, steps, operations, components, parts, or a combination thereof.

A power module according to exemplary embodiments of the present disclosure is described hereafter with reference to the accompanying drawings.

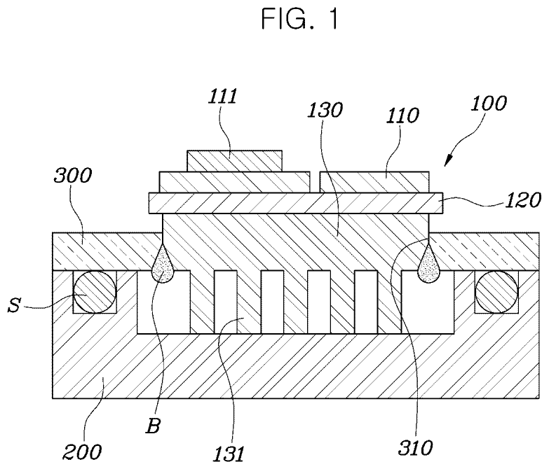

A power module according to an exemplary embodiment of the present disclosure, as shown in FIG. 1, includes: an insulating substrate 100 including a first metal layer 110, an insulating layer 120, and a second metal layer 130 in which a semiconductor chip 111 is disposed on the first metal layer 110 and a heat dissipation portion 131 is formed on the second metal layer 130; a cooling passage 200 forming a cooling channel; and a passage cover 300 including an opening 310 so that the insulating substrate 100 is inserted therein, hermetically sealing the cooling channel by being coupled to the second metal layer 130 and the cooling passage 200, and including the second metal layer 130 coupled to the opening 310 with the insulating layer 100 inserted in the opening 310.

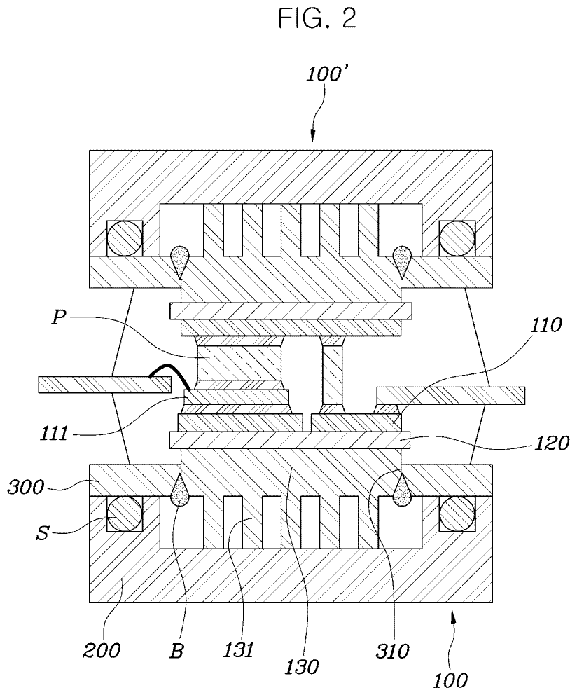

The insulating substrate 100 of the present disclosure may be provided in a pair and the insulating substrates 100 may be connected to each other through a spacer P with the semiconductor chip 111 therebetween, and accordingly, the power module of the present disclosure may be configured as a double-sided-cooling power module as shown in FIG. 2.

The structure shown in FIG. 1 may be understood as a structure in which any one of a pair of insulating substrates 100 facing each other has been omitted or a structure in which the semiconductor chip 111 is disposed on a single substrate.

The insulating substrate 100 according to an exemplary embodiment of the present disclosure includes the first metal layer 110, the insulating layer 120, and the second metal layer 130, in which the first metal layer 110 may be bonded to a first side of the insulating layer 120 and the second insulating layer 130 may be bonded to a second side of the insulating layer 120 with the insulating layer 120 therebetween. The semiconductor chip 111 may be disposed on a first side of the first metal layer 110 and the heating dissipation portion 131 that exchanges heat with a cooling medium flowing through the cooling passage 200 may be disposed on a second side of the second metal layer 130.

The insulating substrate 100 includes main components relating to the power module and an actual power module may include more or less components.

The insulating layer 120 is provided for electrical insulation between the inside and the outside of the power module and may be made of ceramic.

The first metal layer 110 is provided to electrification between the inside and the outside of the power module and includes a pattern on the surface, forming the electrical connection relationship of the power module.

The semiconductor chip 111 is bonded to the first metal layer 110. The semiconductor chip 111 determines electrification of electrical connection by turning on or off in response to switching signals. The semiconductor chip 111 may be implemented as a switching element such as an Insulated Gate Bipolar Transistor (IGBT), a Metal-Oxide-Semiconductor Field-Effect Transistor (MOSFET), or the like, and silicon (Si), silicon carbide (SiC), or the like may be applied as the material.

The second metal layer 130 cools the power module by transmitting heat generated by the semiconductor chip 111 to the outside through heat-exchange. The present disclosure applies a direct cooling type, in which the second metal layer 130 is connected to the cooling passage 200 and exchanges heat with a cooling medium.

The second metal layer 130 includes the heat dissipation portion 131. The heat dissipation portion 131 may be integrally formed with the second metal layer 130 or may be separately manufactured and then coupled to the second metal layer 130. The heat dissipation portion 131 may be made of the same material as the second metal layer 130 and may be formed in a shape securing thermal conductivity.

That is, the heat dissipation portion 131 may be at least one or more fins 135 extending from the second metal layer 130 toward the cooling passage 200. As described above, the heat dissipation portion includes a plurality of fins and the fins are spaced a predetermined distance apart from each other, whereby the heat dissipation area increases and the heat-exchange efficiency may be secured.

Furthermore, the heat dissipation portion 131 may be elongated from the second metal layer 130 toward the cooling passage 200 and the area exposed at the cooling channel increases or decreases, depending on the length of the heat dissipation portion 131, whereby it is possible to satisfy cooling performance required by the power module.

The first metal layer 110 and the second metal layer 130 may be made of copper (Cu) having high thermal conductivity.

Furthermore, the insulating substrate 100 may be manufactured in an Active Metal Brazed (AMB) type or a Direct Bonded Copper (DBC) type.

Meanwhile, the cooling passage 200 forms a cooling channel through which a cooling medium flows and the passage cover 300 is coupled to the second metal layer 130 of the insulating substrate 100 and the cooling passage 200, hermetically sealing the cooling channel.

That is, the cooling passage 200 is coupled to the second metal layer 130 of the insulating substrate 100 through the passage cover 300, forming a sealed cooling channel.

Since a cooling channel is formed by the second metal layer 130 of the insulating substrate 100, the cooling passage 200, and the passage cover 300, it is easy to form a cooling channel and management is easy because it is possible to change the size, shape, etc. of the second metal layer 130, the cooling passage 200, and the passage cover 300 in accordance with the specifications of parts.

The cooling passage 200 may be made of a material which is relatively light and low in cost even though thermal conductivity decreases in comparison to the second metal layer 130 of the insulating substrate 100 and the passage cover 300.

As described above, since the insulating layer 100 and the cooling passage 200 are coupled together through the passage cover 300 in an exemplary embodiment of the present disclosure, it is easy to manufacture and manage the power module. Furthermore, since the second metal layer 130 of the insulating substrate 100 and the passage cover 300 are made of the same material and exchange heat with a cooling medium, cooling efficiency may be secured.

Meanwhile, the passage cover 300 may be made of the same material as the second metal layer 130. For example, the passage cover 300 and the second metal layer 130 include copper (Cu) which is a material having high thermal conductivity, and may be made of various materials as long as the materials have high thermal conductivity.

Furthermore, since the passage cover 300 and the second metal layer 130 are made of the same material having high thermal conductivity, the passage cover 300 also gives cooling effect to the second metal layer 130 by exchanging heat with a cooling medium through the cooling channel, so that the area exposed at the cooling channel increases and accordingly the cooling performance of the power module may be improved.

Meanwhile, when the insulating substrate 100 is inserted in the opening 310 of the passage cover 300, the second metal layer 130 may be positioned to be matched to the passage cover 300 in a direction perpendicular to the insertion direction of the insulating substrate 100.

The opening 310 is formed in a hole shape through the passage cover 300, and the insulating substrate 100 may be inserted through the opening 310.

The second metal layer 130 of the insulating substrate 100 is coupled to the passage cover 300 and is connected to the cooling passage 200 through the passage cover 300. The length of the heat dissipation portion 131 may be set so that when the insulating substrate 100 is inserted in the opening 310 of the passage cover 300, the second metal layer 130 is horizontally matched to the passage cover 300. That is, when the insulating substrate 100 is inserted in the opening 310 of the passage cover 300, the heat dissipation portion 131 of the second metal layer 130 is supported in contact with the cooling passage 200, so that the second metal layer 130 is matched to the opening 310 of the passage cover 300 in the state which they may be coupled to each other.

The external edge portion of the second metal layer 130 and the internal edge portion of the opening 310 may be coupled together by welding with the insulating substrate 100 inserted in the opening 310 of the passage cover 300.

That is, the insulating substrate and the passage cover 300 may be fixed to each other through welding, and since the external edge portion of the second metal layer 130 and the internal edge portion of the opening 310 are welded in a matched state, a coupling force may be secured therebetween. Accordingly, the internal edge portion of the opening 310 of the passage cover 300 may be greater than or equal to the external diameter of the second metal layer 130, the second metal layer 130 is inserted in the opening 310 and the internal surface of the opening 310 and the external surface of the second metal layer 130 are matched to each other, and they may be coupled to each other by welding in the instant state.

Accordingly, the second metal layer 130 of the insulating substrate 100 is coupled to the opening 310 of the passage cover 300, whereby they may be fixed to each other.

Meanwhile, beads B may be formed by welding at the interface between the second metal layer 130 and the opening 310 of the passage cover 300.

Furthermore, the beads B may be formed toward the cooling passage 200 from the second metal layer 130.

That is, beads B are formed by welding when the second metal layer 130 and the opening 310 of the passage cover 300 are welded, so that the second metal layer 130 and the passage cover 300 may be physically coupled together by the beads B. The beads B cover the interface between the second metal layer 130 and the opening 310 of the passage cover 300, whereby the second metal layer 130 and the passage cover 300 may be connected by a stronger coupling force.

Furthermore, since the beads B are formed toward the cooling passage 200 from the second metal layer 130, the beads B cover and fill the gap between the second metal layer 130 and the passage cover 300, whereby leakage of a cooling medium flowing through the cooling channel is prevented. Furthermore, since the beads B are formed in the cooling channel, interference with other parts by the beads B in the power module is prevented.

Meanwhile, the cooling passage 200 forms a sealed space therein by coupling the passage cover 300 thereto and a sealer S may be disposed at the joint between the cooling passage 200 and the passage cover 300.

The sealer S may be a gasket, an O-ring, or the like and a groove in which the sealer S is accommodated may be formed at the passage cover 300 to fix the position of the sealer S.

The sealer S is disposed at the joint of the cooling channel 200 and the passage cover 300, and the cooling channel 200 and the passage cover 300 are coupled together while pressing the sealer S by pressure, whereby sealing performance may be secured.

The power module according to the exemplary embodiment described above, as shown in FIG. 1, may include the insulating substrate 100, the cooling passage 200, and the passage cover 300 at two sides.

The power module of the present disclosure may be manufactured in various embodiments.

As an exemplary embodiment of the present disclosure, modules electrically connected through a space with insulating substrates 100 at two sides are manufactured and then a passage cover 300 is coupled to each of second metal layers 130 of both insulating substrates 100. Thereafter, a cooling passage 200 is coupled to each of both passage covers 300, whereby a power module which may be cooled on both sides may be configured.

Furthermore, as another exemplary embodiment of manufacturing a power module, a passage cover 300 is coupled through welding to each of insulating substrates 100 to be coupled to each other and then both insulating substrates 100 are coupled through a spacer P. A cooling passage 200 is coupled to each of both passage covers 300 in the modules with the insulating substrates 100 coupled, as described above, whereby a power module which may be cooled on both sides may be configured.

Meanwhile, as another exemplary embodiment of the present disclosure, the passage cover 300 may be made of clad metal formed by stacking and coupling different materials.

Clad metal is a complex material formed by coupling different kinds of metal into a single material, so it is possible to take all of the advantages of the coupled metals by use of clad metal. Such clad metal may be manufactured through hot rolling, explosive welding, resistance seam welding, etc.

In detail, the passage cover 300 includes a first material 300a and a second material 300b, in which the first material 300a may be the same as the material of the second metal layer 130 and the second material 300b may be the same as the material of the cooling passage 200.

In the present way, the passage cover 300 may be made of clad metal formed by integrating the first material 300a and the second material 300b, in which the first material 300a may be copper (Cu) the same as the material of the first metal layer 110 and the second metal layer 130 and the second material 300b may be a material which is the same as the material of the cooling passage 200 and relatively light and low in cost.

Accordingly, when the passage cover 300 is coupled to the insulating substrate 100 and the cooling passage 200, it is possible to achieve optimization in consideration of cooling performance, bonding performance, weight, etc.

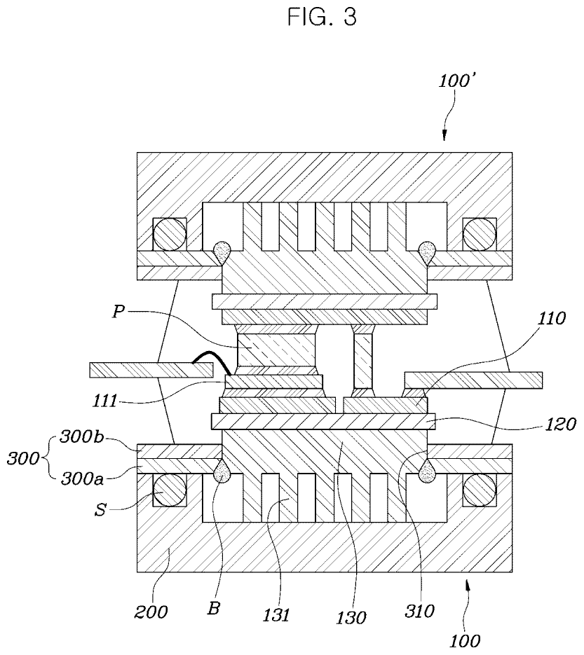

As a corresponding embodiment, as shown in FIG. 3, in the passage cover 300, the first material 300a may be coupled to the second metal layer 130 and the cooling passage 200 and the second material 300b may be positioned opposite to the cooling passage 200.

As described above, since the first material 300a of the passage cover 300 which is the same as the material of the second metal layer 130 of the insulating substrate 100 is coupled to the cooling passage 200, material having high thermal conductivity forms a cooling channel, whereby the area that comes in contact with a cooling medium is increased and it is possible to improve the cooling performance of the power module.

Furthermore, since the second material 300b is coupled to the first material 300a at the opposite side to the cooling passage 200, strength of the passage cover 300 is secured and it is possible to reduce the weight and cost.

In an exemplary embodiment of the present disclosure, beads B may be formed between the first material 300a and the second metal layer 130 in welding as shown in FIG. 3

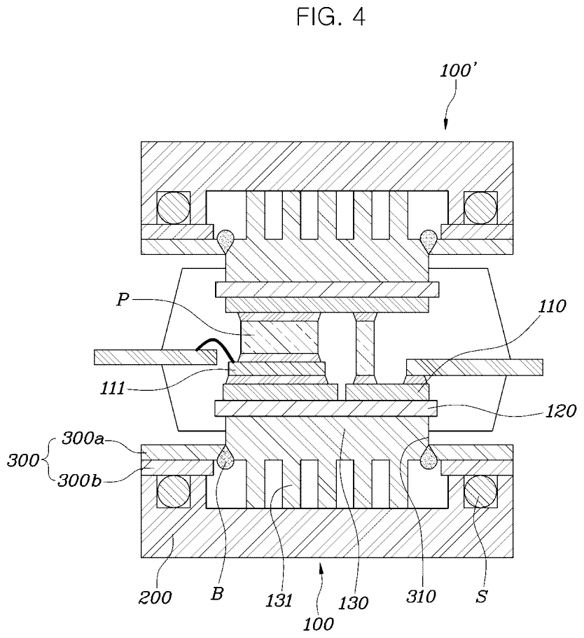

As another exemplary embodiment of the present disclosure, as shown in FIG. 4, in the passage cover 300, the first material 300a may be coupled to the second metal layer 130 and the second material 300b may be disposed between the first material 300a and the cooling passage 200 and coupled to the cooling passage 200.

Since the second material 300b of the passage cover 300 which is the same as the material of the cooling passage 200 is coupled to the cooling passage 200, it is easy to bond the passage cover 300 and the cooling passage 200 and it is possible to improve the bonding quality through strong coupling.

Furthermore, since the first material 300a is bonded to the second metal layer 130 of the insulating substrate 100, bonding ability between the passage cover 300 and the insulating substrate 100 is secured and the cooling performance also may be secured.

In an exemplary embodiment of the present disclosure, the second material 300bof the passage cover 300 is spaced from the second metal layer 130 and a bead B is on a joint between the first material 300a of the passage cover 300 and the second metal layer 130.

Meanwhile, the second metal layer 130 is divided into a first layer 130a and a second layer 130b, in which the first layer 130a is bonded to the insulating layer 120, the heat dissipation portion 131 is formed on the second layer 130b, and the first layer 130a and the second layer 130b may be bonded to each other through an adhesive.

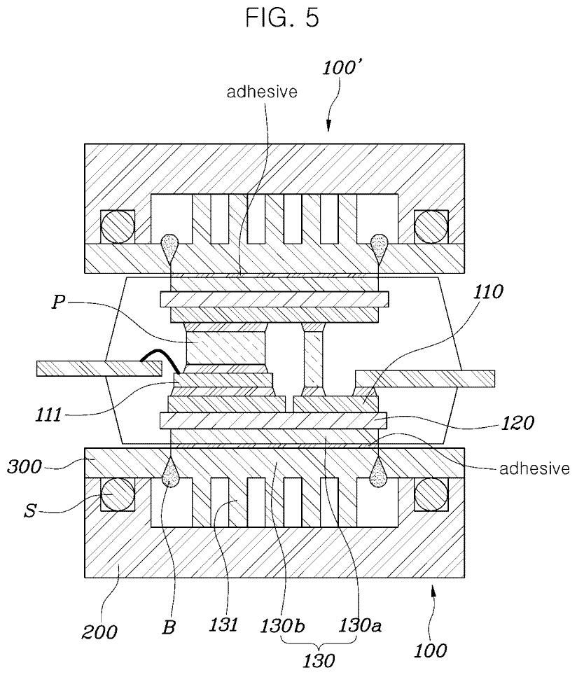

As shown in FIG. 5, the second metal layer 130 is divided into two layers, and the first layer 130a and the second layer 130b are separately manufactured and then bonded by an adhesive, so it is possible to adjust the thickness, size, etc. of the first layer 130a and the second layer 130b to fit to the specifications of the power module and it is possible to design the shape of the heat dissipation portion 131 of the second layer 130b in accordance with the specifications of the power module.

Freedom may be secured in manufacturing by the structure in which the first layer 130a of the second metal layer 130 is bonded to the insulating layer 120 by an adhesive and the second layer 130b is bonded to the first layer 130a by an adhesive.

Meanwhile, in the structure in which the second metal layer 130 is divided into the first layer 130a and the second layer 130b, when the insulating substrate 100 is inserted in the opening 310 of the passage cover 300, the second layer 130b may be positioned in the opening 310 of the passage cover 300 and coupled to the passage cover 300.

Accordingly, the length of the heat dissipation portion 131 may be set so that when the insulating substrate 100 is inserted in the opening 310 of the passage cover 300, the second layer 130b of the second metal layer 130 is horizontally matched to the passage cover 300. That is, when the insulating substrate 100 is inserted in the opening 310 of the passage cover 300, the heat dissipation portion 131 of the second layer 130b is supported in contact with the cooling passage 200, so that the second layer 130b is matched to the opening 310 of the passage cover 300, whereby the second layer 130b and the passage cover 300 may be coupled to each other.

The external edge portion of the second layer 130b and the internal edge portion of the opening 310 of the passage cover 310 may be coupled together by welding with the insulating substrate 100 inserted in the opening 310 of the passage cover 300.

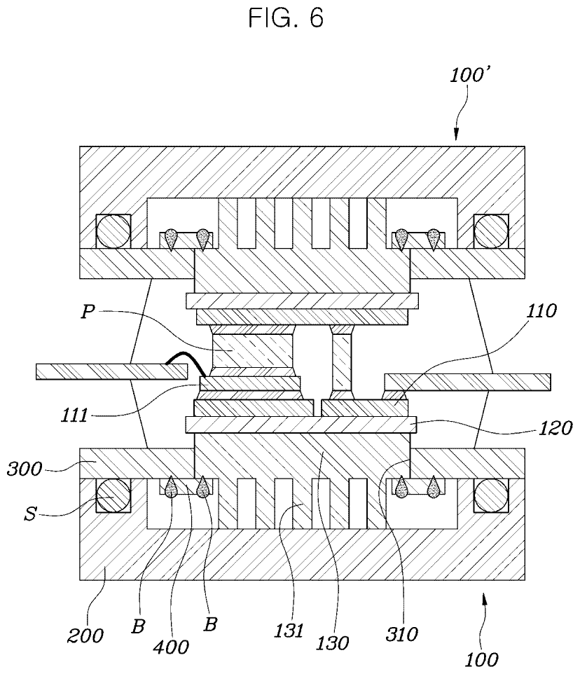

Meanwhile, as shown in FIG. 6, the second metal layer 130 of the insulating substrate 100 and the passage cover 300 may be coupled to each other through a connecting member 400.

The connecting member 400 may be made of the same material as the second metal layer 130.

The connecting member 400 is positioned at the interface of the second metal layer 130 and the passage cover 300 and coupled to the second metal layer 130 and the passage cover 300, coupling the second metal layer 130 and the passage cover 300.

Furthermore, the connecting member 400 is disposed in the cooling channel and hermetically seals the interface between the second metal layer 130 and the passage cover 300, whereby it is possible to secure watertightness.

In detail, the connecting member 400 is welded to the second metal layer 130 on a first side and welded to the passage cover 300 on a second side, and beads B may be formed toward the cooling passage 200 in welding.

Since the connecting member 400 is coupled to the second metal layer 130 and the passage cover 300 through welding in the present way, the second metal layer 130 and the passage cover 300 may be physically coupled together through the connecting member 400 by beads B formed in welding.

Furthermore, since the beads B that are formed when the connecting member 400 is welded are formed in the cooling channel toward the cooling passage 200, the beads B fill gaps which may be formed at the joint between the connecting member 400 and the second metal layer 130 and the joint between the connecting member 400 and the passage cover 300, preventing leakage of a cooling medium. Furthermore, since the beads B are formed in the cooling channel, interference with other parts by the beads B in the power module is prevented.

The connecting member 400 may be a portion of the second metal layer 130 or the passage cover 300. That is, the connecting member 400 may be integrated and elongated with the second metal layer 130 or may be integrated and elongated with the passage cover 300.

Accordingly, since the connecting member 400 is integrated with the second metal layer 130 or the passage cover 300, it is easy to manage. Furthermore, there is no problem of leakage of a cooling medium at the integrated region, so watertightness may be secured.

According to the power module including the structure described above, the substrate and the cooling passage 200 are directly coupled together, so that the cooling performance of the power module is improved.

Furthermore, it is possible to improve cooling performance and secure watertightness of the cooling channel through the connection structure of the substrate, the cooling passage 200, and the cooling cover that form the cooling channel.

Meanwhile, each of FIGS. 2 and 3, the reference sign “M” denotes a molding portion, wherein the molding portion M may be made of, for example, epoxy plastic material and partially or completely covers components inside the power module to block electrical connection with the outside.

The reference sign “W” denotes a connection portion, wherein the connection portion W may be made of metal wire as a wire bonding and be made of, for example, gold (Au), aluminum (Al), copper (Cu).
The reference sign “L” denotes a lead portion, wherein the lead portion L is provided as a signal pin for electrical connection between the components inside the power module, and for example, may be made of a metal material that can conduct electricity.

Furthermore, it is easy to manufacture and manage the power module, and the operation performance and the operation reliability of the power module are improved because the cooling performance and watertightness of the power module are secured, so that the power density of an inverter applied to the power module may be increased.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
an insulating substrate including a first metal layer, an insulating layer, and a second metal layer, wherein a semiconductor chip is disposed on the first metal layer and a heat dissipation portion is formed on the second metal layer;
a cooling passage forming a cooling channel in the cooling passage; and
a passage cover including an opening so that the insulating substrate is inserted in the opening, and configured to hermetically seal the cooling channel by being coupled to the second metal layer and the cooling passage, wherein the second metal layer is coupled to the opening with the insulating layer inserted in the opening.

2. The power module of claim 1, wherein the passage cover and the second metal layer are made of a same material.

3. The power module of claim 1, wherein the insulating substrate is inserted in the opening of the passage cover, and the second metal layer is positioned to be matched to the passage cover in a direction perpendicular to an insertion direction of the insulating substrate.

4. The power module of claim 1, wherein an external edge portion of the second metal layer and an internal edge portion of the opening are coupled together by welding with the insulating substrate inserted in the opening of the passage cover.

5. The power module of claim 4, wherein beads are formed by welding at an interface between the second metal layer and the opening.

6. The power module of claim 5, wherein the beads are formed on the second metal layer toward the cooling passage.

7. The power module of claim 4, wherein the internal edge portion of the opening of the passage cover is greater than or equal to the external diameter of the second metal layer.

8. The power module of claim 1, wherein the cooling passage forms a sealed space in the cooling passage by coupling the passage cover to the cooling passage and a sealer is disposed at a joint between the cooling passage and the passage cover.

9. The power module of claim 1, wherein the heat dissipation portion includes at least one fin extending from the second metal layer toward the cooling passage.

10. The power module of claim 1, wherein the passage cover is made of clad metal formed by stacking and coupling different materials.

11. The power module of claim 10, wherein the passage cover is made of a first material and a second material, the first material is the same as a material of the second metal layer, and the second material is the same as a material of the cooling passage.

12. The power module of claim 11, wherein the first material of the passage cover is coupled to the second metal layer and the cooling passage, and the second material of the passage cover is positioned opposite to the cooling passage.

13. The power module of claim 11, wherein the first material of the passage cover is coupled to the second metal layer and the second material of the passage cover is disposed between the first material and the cooling passage and coupled to the cooling passage.

14. The power module of claim 13, wherein the second material of the passage cover is spaced from the second metal layer and a bead is on a joint between the first material of the passage cover and the second metal layer.

15. The power module of claim 1, wherein the second metal layer includes a first layer and a second layer, the first layer is bonded to the insulating layer, the heat dissipation portion is formed on the second layer, and the first layer and the second layer are bonded to each other through an adhesive.

16. The power module of claim 15, wherein the insulating substrate is inserted in the opening of the passage cover and the second layer is positioned in the opening of the passage cover and coupled to the passage cover.

17. The power module of claim 1, wherein the second metal layer of the insulating substrate and the passage cover are coupled to each other through a connecting member.

18. The power module of claim 17, wherein the connecting member is welded to the second metal layer on a first side of the connecting member and welded to the passage cover on a second side of the connecting member, and beads are formed at the first and second sides of the connecting member toward the cooling passage in welding.

19. The power module of claim 17, wherein the connecting member is a portion of the second metal layer or the passage cover.
